(19) United States
(12) Patent Application Publication
(10) Pub. No.: US 2023/0027390 A1
(43) Pub. Date: Jan. 26, 2023

(54) IMAGE SENSOR

(71) Applicant: Samsung Electronics Co., Ltd., Suwon-si (KR)

(72) Inventor: Kyongsoon Cho, Incheon (KR)

(21) Appl. No.: 17/689,558

(22) Filed: Mar. 8, 2022

(30) Foreign Application Priority Data
Jul. 14, 2021 (KR) 10-2021-0092484

(51) Int. Cl. H01L 27/146

(52) U.S. Cl. CPC H01L 27/14636; H01L 27/14643; H01L 27/14621; H01L 27/14627; H01L 27/14603

(57) ABSTRACT

An image sensor includes a first chip structure, a second chip structure disposed on the first chip structure, and in which pixels which each include a photoelectric conversion element are defined, and a light-transmissive cover bonded to an edge region of the second chip structure by an adhesive layer and having a recess portion covering a region in which the pixels are accommodated, wherein the second chip structure includes a substrate having a first surface and a second surface opposite to each other, color filters disposed on the second surface of the substrate to correspond to the pixels, a cover insulating layer covering the color filters, and accommodated in the recess portion and disposed to be horizontally spaced apart from an outer boundary of the recess portion, and microlenses disposed on the cover insulating layer to correspond to the pixels, respectively. An upper surface of the cover insulating layer is at a higher vertical level than the second surface of the substrate, and has a step difference of 3 μm to 15 μm with respect to the upper surface of the substrate.

### CROSS-REFERENCE TO RELATED APPLICATIONS

This application claims benefit of priority to Korean Patent Application No. 10-2021-0092484 filed on Jul. 14, 2021 in the Korean Intellectual Property Office, the disclosure of which is incorporated herein by reference in its entirety.

### BACKGROUND

### 1. Field

The present inventive concept relates to an image sensor.

### 2. Description of Related Art

An image sensor for capturing an image and converting the image into an electrical signal is widely used not only in various electronic devices such as digital cameras, mobile phone cameras, and portable camcorders, but also in cameras mounted on automobiles, security devices, and robots. Since miniaturization and high resolution of the image sensor are important, various studies are being conducted to satisfy the demand for miniaturization and high resolution of the image sensor.

### SUMMARY

An aspect of the present inventive concept is to provide an image sensor in which an adhesive layer is prevented from penetrating into a pixel array region in a process of bonding wafers with the adhesive layer.

According to an aspect of the present inventive concept, an image sensor includes: a first chip structure, a second chip structure disposed on the first chip structure, and in which pixels which each include a photoelectric conversion element are defined, and a light-transmissive cover bonded to an edge region of the second chip structure by an adhesive layer and having a recess portion covering a region in which the pixels are accommodated, wherein the second chip structure includes a substrate having a first surface and a second surface opposite to each other, color filters disposed on the second surface of the substrate to correspond to the pixels, a cover insulating layer covering the color filters, and accommodated in the recess portion and disposed to be horizontally spaced apart from an outer boundary of the recess portion, and microlenses disposed on the cover insulating layer to correspond to the pixels, respectively. An upper surface of the cover insulating layer is at a higher vertical level than the second surface of the substrate, and has a step difference of 3 μm to 15 μm with respect to the upper surface of the substrate.

According to an aspect of the present inventive concept, an image sensor includes: a substrate in which pixels which each include a photoelectric conversion element are defined, the substrate having a first surface and a second surface opposite to each other, a light-transmissive cover bonded to an edge region of the second surface on the second surface of the substrate by an adhesive layer and having a recess portion covering a region in which the pixels are accommodated, a cover insulating layer disposed on the second surface of the substrate, and accommodated in the recess portion and disposed to be horizontally spaced apart from an outer boundary of the recess portion, and microlenses disposed on the cover insulating layer to correspond to the pixels, respectively. The cover insulating layer is at a higher vertical level than the second surface of the substrate and has a step difference with respect to the second surface of the substrate in a range of 3 μm to 15 μm.

According to an aspect of the present inventive concept, an image sensor includes: a substrate on which pixels which each include a photoelectric conversion element are disposed, the substrate having a first surface opposite to a second surfaces, a support platform having a first surface connected to the first surface of the substrate and a second surface opposite thereto, the support platform including an inner wall connecting the first surface of the support platform to the second surface of the support platform and having a light-transmissive window in which the pixels are accommodated, a light-transmissive substrate disposed on the second surface of the support platform, and covering the light-transmissive window, color filters disposed on the first surface of the substrate to correspond to the pixels, a cover insulating layer covering the color filters and accommodated in the light-transmissive window and disposed to be horizontally spaced apart from a sidewall of the light-transmissive window, and microlenses disposed on the cover insulating layer to correspond to the pixels, respectively. The cover insulating layer is at a higher vertical level than the first surface of the substrate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a block diagram illustrating an image sensor according to an example embodiment of the present inventive concept;

FIG. 2 is a circuit diagram illustrating a pixel circuit of a pixel included in an image sensor according to an example embodiment of the present inventive concept;

FIG. 3 is a perspective view of an image sensor according to an example embodiment of the present inventive concept;

FIG. 4 is an exploded perspective view of the image sensor of FIG. 3;

FIG. 5 is a plan view of the second chip structure of FIG. 4;

FIG. 6 is a cross-sectional view taken along line I-I′ of FIG. 3;

FIGS. 7 and 8 are modified examples of the cover insulating layer shown in FIG. 5; and

FIGS. 9 to 15 are cross-sectional views illustrating example embodiments of a method of forming an image sensor according to an example embodiment of the present inventive concept.

### DETAILED DESCRIPTION

Hereinafter, example embodiments of the present inventive concept will be described with reference to the accompanying drawings.

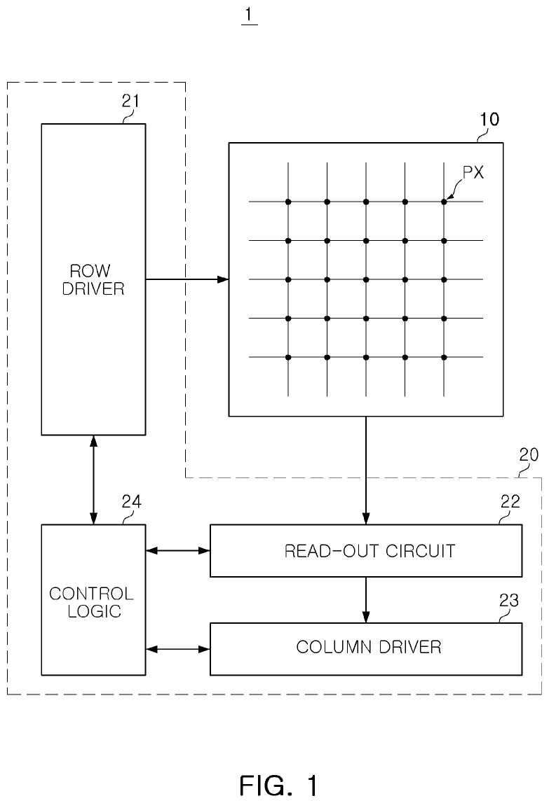

FIG. 1 is a block diagram illustrating an image sensor according to an example embodiment of the present inventive concept.

Referring to FIG. 1, an image sensor 1 may include a pixel array 10 and a controller 20.

The pixel array 10 may include pixels PX arranged in an array form along a plurality of rows and a plurality of columns. Each of the pixels PX may include a photodiode generating a charge in response to an optical signal incident from an external source, and a pixel circuit generating an electrical signal corresponding to the charge generated by the photodiode. For example, the pixel circuit may include a floating diffusion region, a storage transistor, a transfer transistor, a reset transistor, a driving transistor, a selection transistor, and the like. The configuration of the pixels PX may vary according to example embodiments. For example, each of the pixels PX may include an organic photodiode including an organic material, unlike a silicon photodiode, or may be implemented as a digital pixel. When the pixels PX are implemented as digital pixels, each of the pixels PX may include a comparator, a counter converting an output of the comparator into a digital signal, and the like.

The controller 20 may include circuits for controlling the pixel array 10. For example, the controller 20 may include a row driver 21, a readout circuit 22, a column driver 23, a control logic 24, and the like. The row driver 21 may drive the pixel array 10 in units of rows. For example, the row driver 21 may generate a transfer control signal for controlling a transfer transistor of the pixel circuit, a reset control signal for controlling the reset transistor, a selection control signal for controlling the selection transistor, and the like, and input the same to the pixel array 10.

The readout circuit 22 may include a comparator, a dynamic bias switching (DBS) circuit converting an output of the comparator into a digital signal, and the like. The comparator may be connected to the pixels PX included in a row selected by a row select signal supplied by the row driver 21 through column lines, and perform correlated double sampling and compare a reset voltage and a pixel voltage with a ramp voltage to output an analog timing signal. The DBS circuit may convert the analog timing signal output by the comparator into a digital signal and transmit the same to the column driver 23. The DB S circuit may include a counter circuit, or the like.

The column driver 23 may include a latch or buffer circuit capable of temporarily storing a digital signal, an amplifier circuit, and the like, and may process a digital signal received from the readout circuit 22. The row driver 21, the readout circuit 22, and the column driver 23 may be controlled by the control logic 24. The control logic 24 may include a timing controller for controlling operation timings of the row driver 21, the readout circuit 22 and the column driver 23, an image signal processor for processing image data, and the like.

The control logic 24 may generate image data by signal processing data output from the readout circuit 22 and the column driver 23. In addition, the control logic 24 may control operation timings of the row driver 21, the readout circuit 22, and the column driver 23.

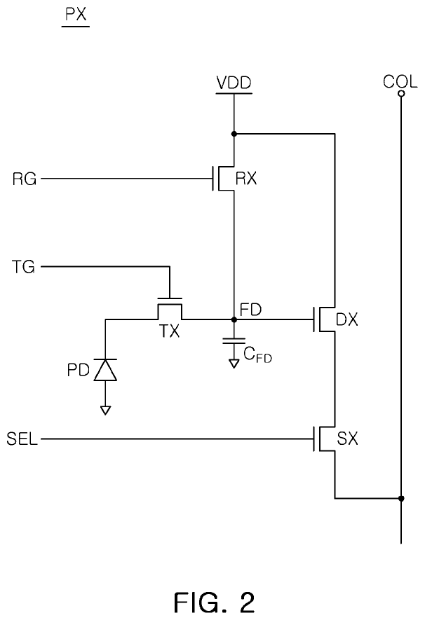

FIG. 2 is a circuit diagram illustrating a pixel circuit of a pixel included in an image sensor according to an example embodiment of the present inventive concept.

Referring to FIG. 2, each of the pixels PX according to an example embodiment may include a plurality of transistors and a photodiode PD. Signals generated by the transistors using the charges generated by the photodiode PD may be output through a column line COL.

The pixels PX may include a transfer transistor TX, a reset transistor RX, a driving transistor DX, a selection transistor SX, and the like. The reset transistor RX may be turned on and off by the reset control signal RG, and when the reset transistor RX is turned on, a voltage of the floating diffusion region FD may be reset to the power supply voltage VDD. When the voltage of the floating diffusion region FD is reset, the selection transistor SX may be turned on by the selection control signal SG to output the reset voltage to the column line COL.

In an example embodiment, the photodiode PD may generate electrons or holes as primary charge carriers in response to light. When the transfer transistor TX is turned on after the reset voltage is output to the column line COL, the charge generated by exposing the photodiode PD to light can move to a capacitor CFD of the floating diffusion region FD. The driving transistor DX may operate as a source-follower amplifier amplifying the voltage of the floating diffusion region FD, and when the selection transistor SX is turned on by the selection control signal SG, a pixel voltage corresponding to the charge generated by the photodiode PD may be output to the column line COL.

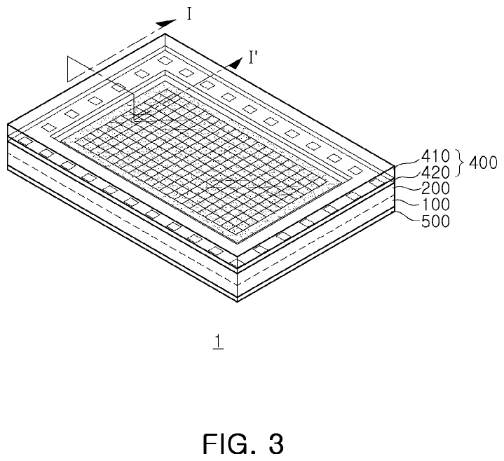

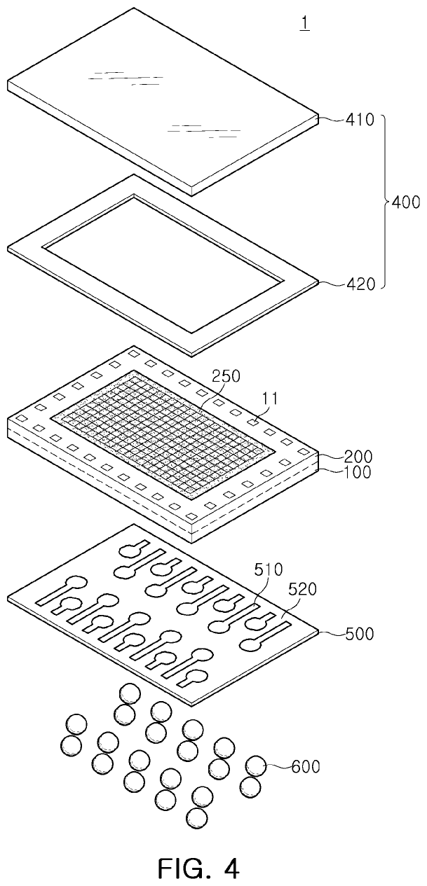

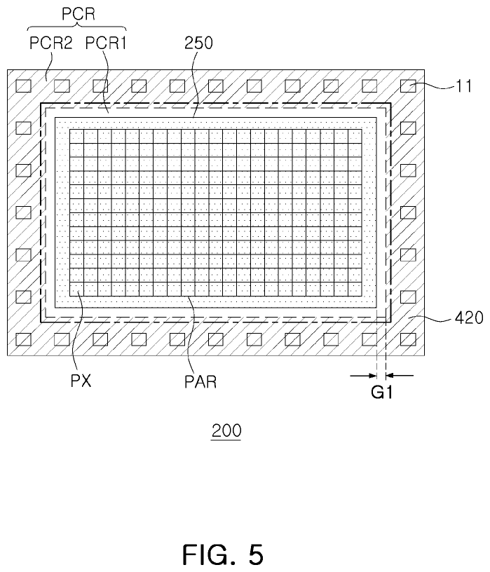

An image sensor according to an example embodiment of the present inventive concept will be described with reference to FIGS. 3 to 5. FIG. 3 is a perspective view of an image sensor according to an example embodiment of the present inventive concept, and FIG. 4 is an exploded perspective view of the image sensor of FIG. 3. FIG. 5 is a plan view of the second chip structure of FIG. 4.

Referring to FIGS. 3 and 4, an image sensor 1 according to an example embodiment may include a first chip structure 100, a second chip structure 200, a light-transmissive cover 400, and a redistribution structure 500. The first chip structure 100 may be a logic chip, and the second chip structure 200 may be an image sensor chip including pixels. According to an example embodiment, the first chip structure 100 may be a stacked chip structure including a logic chip and a memory chip. A “chip” as described herein refers to a die, for example formed from a wafer, including an integrated circuit formed therein or thereon. For example, the die may be a semiconductor die. The second chip structure 200 may be stacked on the first chip structure 100. The first chip structure 100 and the second chip structure 200 may be directly bonded to each other without an additional adhesive material.

A light-transmissive cover 400 for protecting an upper surface of the second chip structure 200 may be bonded to the upper surface of the second chip structure 200. The light-transmissive cover 400 may include a light-transmissive substrate 410 and a support portion 420.

A redistribution structure 500 may be disposed on a lower surface of the first chip structure 100. The redistribution structure 500 may include a conductive pattern 510 and an insulating layer 520 covering the conductive pattern 510. A lower connection terminal 600 may be disposed on a portion of the conductive pattern 510 through the insulating layer 520. The lower connection terminal 600 may be referred to as a bump, and may be in the form of a conductive bump or ball. Though described above in the singular, both the conductive pattern 510 and lower connection terminal 600 are one of a plurality of conductive patterns and lower connection terminals 600.

Referring to FIG. 5, the second chip structure 200 may include a pixel array region PAR and a peripheral circuit region PCR outside thereof. The pixel array region PAR may have a configuration corresponding to the pixel array 10 of FIG. 1, and the peripheral circuit region PCR may have a configuration corresponding to the controller 20 of FIG. 1. The peripheral circuit region PCR includes a logic region PCR1 and a pad region PCR2, and refers to a region other than the pixel array region PAR. The peripheral circuit region PCR may surround the pixel array region PAR, from a plan view. The pad region PCR2 may include a plurality of electrode pads 11, and the pixel array region PAR may include pixels PX arranged in a matrix form. For example, the electrode pads 11 may be input/output pads for transmitting/receiving electrical signals to and from an external device. For example, the electrode pads 11 may serve to transfer driving power such as a power voltage or a ground voltage supplied from an external power source to circuits disposed in the peripheral circuit region PCR of the image sensor 1. The logic region PCR1 may be disposed along edges of the pixel array region PAR. The logic region PCR1 is illustrated as being positioned along all four edges of the pixel array region PAR, but is not limited thereto, and may be positioned along two or three edges.

A cover insulating layer 250 covering the pixel array region PAR (e.g., to overlap the pixel array region PAR from a plan view) may be disposed on an upper surface of the second chip structure 200. The cover insulating layer 250 may be disposed so as not to cover the plurality of electrode pads 11 in the pad region PCR2 (e.g., not to overlap the electrode pads 11 from the plan view) while covering the pixel array region PAR. The cover insulating layer 250 may be disposed with a predetermined separation distance G1 (e.g., in a horizontal direction) from the support portion 420 so as not to overlap (e.g., from the plan view, or vertical direction) the support portion 420 of the light-transmissive cover 400 described above.

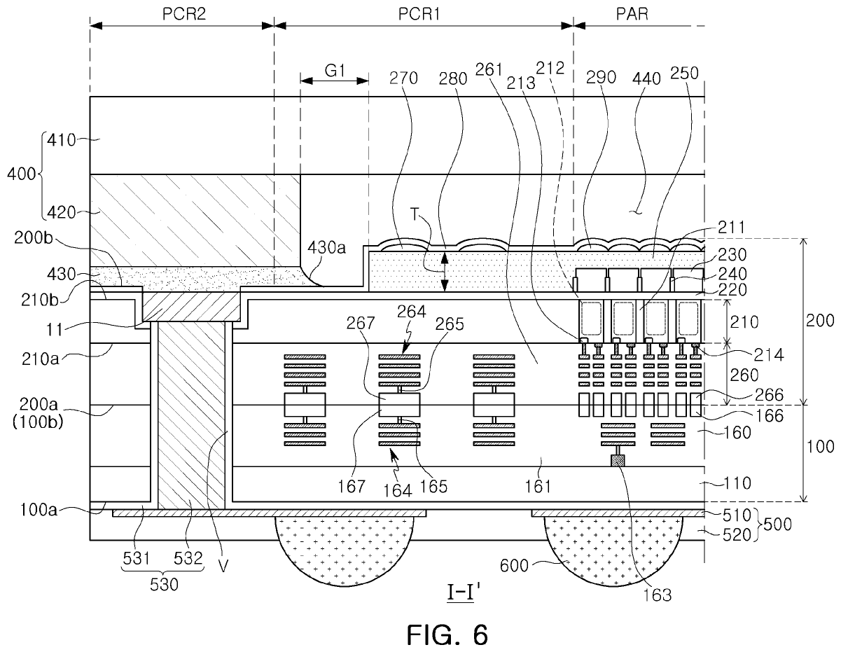

Referring to FIG. 6, an image sensor 1 according to an example embodiment will be described in detail. FIG. 6 is a cross-sectional view taken along line I-I′ of FIG. 3.

Referring to FIG. 6, in the image sensor 1 according to an example embodiment, a light-transmissive cover 400, a second chip structure 200, a first chip structure 100, and a redistribution structure 500 are sequentially stacked and disposed.

The light-transmissive cover 400 may be attached on the second chip structure 200. The light-transmissive cover 400 may include a light-transmissive substrate 410 and a support portion 420. A recess portion 440, also described as a recess, in which the cover insulating layer 250 of the second chip structure 200 can be accommodated may be formed in the light-transmissive cover 400. A top boundary of the recess portion 440 may be provided by a lower surface of the light-transmissive substrate 410, and a side boundary of the recess portion 440 may be provided by a sidewall of the support portion 420. The recess portion 440 may include empty space (e.g., filled with air, but not including any solid components). The recess portion 440 may be formed so that the pixels of the second chip structure 200 are formed in a region covered by the recess portion 440.

The light-transmissive substrate 410 may cover an upper surface 200b of the second chip structure 200, and may be disposed to be spaced apart from the upper surface 200b of the second chip structure 200. The light-transmissive substrate 410 may be made of a light-transmissive material. Specifically, the light-transmissive substrate 410 may be formed of one of soft glass, fused silica, and fused quartz.

The support portion 420 may be understood as a support maintaining a gap between the light-transmissive substrate 410 and the second chip structure 200. The support portion 420 may be disposed along an edge region of the light-transmissive substrate 410 (e.g., when viewed from a plan view) to have a partition wall structure blocking an inside of the recess portion 440 from an outside of the image sensor. The sidewalls of the support portion 420 (e.g., inner sidewalls, which connect a top surface to a bottom surface of the support portion 420) may form a light-transmissive window through which light is incident on the second chip structure 200. The cover insulating layer 250 may be formed in the light-transmissive window.

The support portion 420 may be attached to the upper surface 200b of the second chip structure 200 through an adhesive layer 430 applied to a lower surface. The adhesive layer 430 may be applied to cover the lower surface of the support portion 420. However, the present inventive concept is not limited thereto, and in a process of attaching the support portion 420 to the second chip structure 200 after being applied to a region of the lower surface of the support portion 420, the adhesive layer 430 may be pressed by the support portion 420, such that it may be interposed between the lower surface of the support portion 420 and the upper surface 200b of the second chip structure 200. The adhesive layer 430 is pressed by the support portion 420 while the support portion 420 is attached to the second chip structure 200, so that a portion 430a of the adhesive layer 430 may penetrate into the recess portion 440. The support portion 420 may be made of a photosensitive resin. In one embodiment, the support portion 420 may be formed of a photoresist. The support portion 420 may also be described as a support platform, a ring-shaped support platform (e.g., having a rectangular ring shape from a plan view), a support ring, or a substrate holder or riser (on which light transmission substrate 410 is mounted).

The first chip structure 100 may include a first substrate 110 and a first wiring structure 160.

The first substrate 110 may be, for example, a silicon-on-insulator (SOI). A logic circuit gate layer 163 may be formed on a lower surface 110a of the first substrate 110. The logic circuit gate layer 163 may be included in a logic transistor. The logic transistor may be included in a logic circuit that provides a constant signal to each of the pixels of the pixel array region PAR or controls an output signal.

The first wiring structure 160 may include a first wiring insulating film 161, a first connection wiring 164, a upper bonding pad via 165, a first upper bonding pad 166, and a second upper bonding pad 167. The second upper bonding pad 167 may be connected to the first connection wiring 164 through the upper bonding pad via 165.

The second chip structure 200 may include a second substrate 210, a second wiring structure 260, color filters 230, a cover insulating layer 250, and microlenses 290. The second chip structure 200 may include a lower surface 200a and an upper surface 200b opposite to each other.

The second substrate 210 may include a pixel array region PAR and a peripheral circuit region PCR included in the second chip structure 200. The second substrate 210 may be bulk silicon or a silicon substrate. The second substrate 210 may include a lower surface 210a and an upper surface 210b opposite to each other.

A storage node region 213, a pixel isolation region 211, and a photoelectric conversion element 212 may be formed in the pixel array region PAR of the second substrate 210. A pixel gate layer 214 may be formed in a region corresponding to the pixel array region PAR of the lower surface 210a of the second substrate 210.

The storage node region 213 may be formed in the second substrate 210. The storage node region 213 may be spaced apart from the photoelectric conversion element 212. The storage node region 213 may include impurities of a conductivity-type different from that of the second substrate 210. The storage node region 213 may correspond to the floating diffusion region FD of FIG. 2.

The photoelectric conversion element 212 may be disposed in the second substrate 210. The photoelectric conversion element 212 may be a region corresponding to the photodiode PD of FIG. 2. The photoelectric conversion element 212 may generate photocharges in proportion to an amount of light incident from an external source. The photoelectric conversion element 212 may receive light and convert an optical signal into an electrical signal. The photoelectric conversion element 212 according to an example embodiment may include a semiconductor photoelectric conversion element.

The photoelectric conversion element 212 may be formed by doping impurities in the second substrate 210. For example, a difference in impurity concentration may exist between an upper portion and a lower portion of the photoelectric conversion element 212 so that the photoelectric conversion element 212 may have a potential gradient. For example, the photoelectric conversion element 212 may be formed in a form in which a plurality of impurity regions are stacked.

The pixel isolation region 211 may be disposed to surround a side surface of the photoelectric conversion element 212. The pixel isolation region 211 may prevent photocharges generated in a specific pixel by incident light from moving to an adjacent pixel by random drift. In addition, the pixel isolation region 211 may refract incident light obliquely incident on the photoelectric conversion element 212. When the second substrate 210 is formed of silicon, the pixel isolation region 211 includes, for example, a silicon oxide film, a silicon nitride film, an un-doped polysilicon film, air, or combinations thereof.

The pixel gate layer 214 may form a gate electrode of a pixel circuit element disposed in each of the pixels PX disposed in the pixel array region PAR. The pixel gate layer 214 may be a gate electrode included in one of the transfer transistor TG, the reset transistor RX, the source follower transistor SF, and the selection transistor SEL of FIG. 2.

An interlayer insulating layer 220 may be disposed on the upper surface 200b of the second substrate 210. The interlayer insulating layer 220 may include an insulating material. For example, the interlayer insulating layer 220 may include a silicon oxide film. In some example embodiments, the interlayer insulating layer 220 may be omitted.

The color filters 230 may be disposed on the interlayer insulating layer 220. The color filters 230 may be disposed above the photoelectric conversion element 212. The color filter 230 may be disposed in the pixel array area PAR of the second substrate 210. The color filter 230 may pass light of a specific wavelength to reach the photoelectric conversion element 212 therebelow. The color filter 230 may be implemented as a color filter array including, for example, at least one of a red (R) filter, a green (G) filter, and a blue (B) filter. The color filter 230 may be formed of, for example, a material obtained by mixing a resin and a pigment including a metal or a metal oxide.

The cover insulating layer 250 may be disposed on the upper surface 200b of the second substrate 210 to cover the color filter 230. The cover insulating layer 250 may be formed to have a size and thickness that can be accommodated in the recess portion 440 of the light-transmissive cover 400. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The cover insulating layer 250 may have a thickness T of 3 μm to 15 μm. An upper surface of the cover insulating layer 250 may be disposed to have a higher level than the upper surface 200b of the second substrate 210, and the upper surface of the cover insulating layer 250 may have a step difference of 3 μm to 15 μm corresponding to the thickness T of the cover insulating layer 250 from the upper surface 210b of the second substrate 210. In some cases, the interlayer insulating layer 220 may be omitted such that the upper surface 210b of the second substrate 210 coincides with what is shown in FIG. 6 as the top surface of the interlayer insulating layer 220. Or, the interlayer insulating layer 220 in some cases may be considered to be part of the substrate 210, since it may be an oxidized portion of the semiconductor material that forms the substrate 210. The cover insulating layer 250 may contact a top surface of the interlayer insulating layer 220 or substrate 210, and may also contact a top surface of the color filters 230. A “higher level” or “higher vertical level,” as described herein, refers to a higher vertical level, e.g., in a vertical direction perpendicular to the lower surface 210a of the second substrate 210.

In addition, the side surface of the cover insulating layer 250 may be formed to a size that can be spaced apart from an outer boundary of the recess portion 440 with a separation distance G1. In an example embodiment, the separation distance G1 may be 5 μm to 300 μm. The cover insulating layer 250 may be formed to cover a portion of the logic region PCR1 within a range not in contact with the sidewall of the support portion 420 while covering the pixel array region PAR.

The cover insulating layer 250 may have a flat upper surface, and microlenses 290 may be disposed on the upper surface of the cover insulating layer 250. For example, the cover insulating layer 250 may be used as a planarization material layer for planarizing the surface on which the microlenses 290 are disposed.

In some example embodiments, the color filter 230 may be embedded in the cover insulating layer 250. In some example embodiments, the cover insulating layer 250 may have a multilayer structure. The cover insulating layer 250 may include an insulating material. For example, the cover insulating layer 250 may include a resin layer, an oxide film, or a combination thereof.

As described above, the cover insulating layer 250 may have a step difference from the upper surface 200b of the second substrate 210, and may be spaced apart from the outer boundary of the recess portion 440 by a separation distance G1. Therefore, in a process in which the support portion 420 is attached to the second chip structure 200, even if the adhesive layer 430 is pressed by the support portion 420, and a portion 430a of the adhesive layer 430 penetrates into the recess portion 440, the cover insulating layer 250 may be used as a dam to block the portion 430a of the adhesive layer 430 that has penetrated. In this case, the adhesive layer 430 may have a portion 430a in a region overlapping (e.g., horizontally between and at the same vertical level as) a region between the outer boundary of the recess portion 440 and a side surface of the cover insulating layer 250. Accordingly, it is possible to prevent the portion 430a of the adhesive layer 430 from penetrating into the recess portion 440 and being disposed on the upper surface of the cover insulating layer 250 to cover the pixel array region PAR. In particular, by using a step height of 3 μm to 15 μm for the cover insulating layer 250, the step difference can be high enough to prevent the flow of the adhesive layer 430 onto a top of the cover insulation layer 250 (in some cases particularly when the separation distance G1 is 5 μm to 300 μm), and also within a range to still allow proper operation of the microlens and filter array (e.g., to maintain the microlenses 290 within a functional height range above color filters 230).

Microlenses 290 may be disposed on an upper surface of the cover insulating layer 250. The microlenses 290 may be disposed in the pixel array area PAR to overlap the color filters 230, respectively. The microlenses 290 may change a path of light incident to a region other than the photoelectric conversion element 212 to focus the light into the photoelectric conversion element 212. The microlens 190 may include, for example, an organic material such as a light-transmissive resin, but is not limited thereto.

Dummy microlenses 270 may be disposed on an upper surface of the cover insulating layer 250 other than the pixel array area PAR. For example, dummy microlenses 270 may be disposed on the upper surface of the cover insulating layer 250 corresponding to the logic region PCR1. The dummy microlenses 270 may form irregularities on the upper surface of the cover insulating layer 250 to further enhance an effect of blocking the portion 430a of the adhesive layer 430 penetrating into the recess portion 440. For this blocking effect, the dummy microlenses 270 may be formed to have a larger diameter than the microlenses 290, and a pitch of the dummy microlenses 270 is larger than the pitch of the microlenses 290. The thickness of the cover insulating layer 250 may be greater than a thickness of the dummy microlenses 270. In some embodiments, the dummy microlenses 270 do not cover operational photoelectric conversion elements.

According to example embodiments, a protective layer 280 covering the microlenses 290 and the dummy microlenses 270 may be formed. The protective layer 280 may be formed to cover upper surfaces and side surfaces of the microlenses 290 and the dummy microlenses 270 and the cover insulating layer 250.

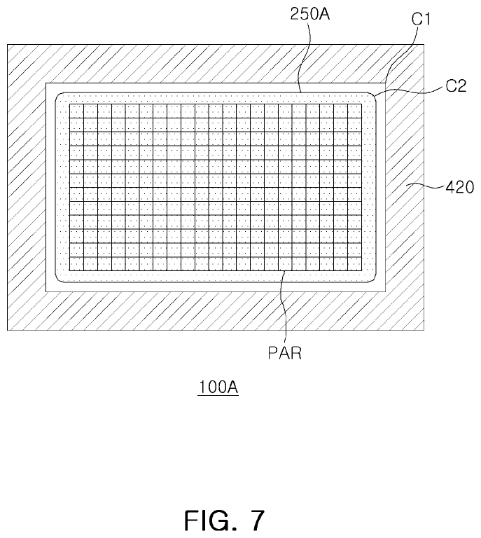

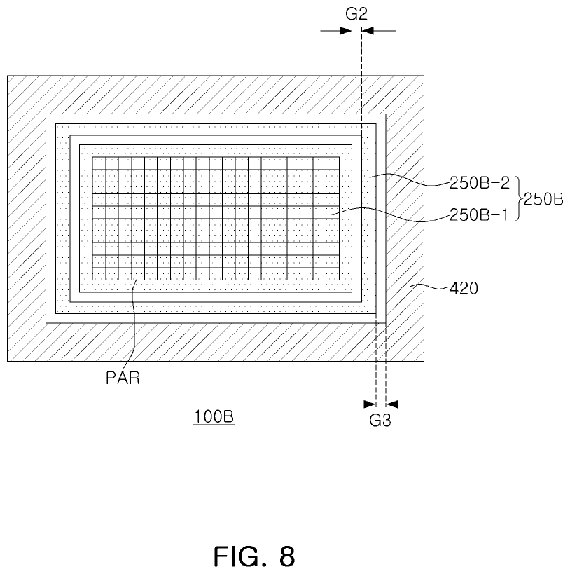

The above-described cover insulating layer 250 may be variously modified. A modified example of the cover insulating layer 250 will be described with reference to FIGS. 7 and 8. FIGS. 7 and 8 are modified examples of the cover insulating layer shown in FIG. 5. Configurations indicated by the same reference numerals as those of the above-described embodiments are the same configurations as those of the above-described embodiments, and thus a detailed description thereof will be omitted.

Referring to FIG. 7, each corner C2 of a cover insulating layer 250A disposed on a first substrate 100A according to an example embodiment may be rounded. An adhesive applied to attach the support portion 420 to the first substrate 100A tends to penetrate more into the recess portion at each corner C1 of the support portion 420. When each corner C2 of the cover insulating layer 250A is rounded, a distance between the corner C2 of the cover insulating layer 250A and the corner C1 of the support portion 420 is increased, so that it is possible to more effectively block an adhesive from penetrating into the recess portion at each corner C1 of the support portion 420 to cover the pixel array region PAR.

Referring to FIG. 8, a cover insulating layer 250B disposed on a first substrate 100B according to an example embodiment may include a first cover insulating layer 250B-1 and a second cover insulating layer 250B-2. The first cover insulating layer 250B-1 may be disposed to overlap the pixel array region PAR, and the second cover insulating layer 250B-2 may be disposed on an external side of the second cover insulating layer 250B-2. According to an example embodiment, the second cover insulating layer 250B-2 may be disposed to surround an external side of the first cover insulating layer 250B-1.

The first cover insulating layer 250B-1 and the second cover insulating layer 250B-2 may be formed of the same material, and may be simultaneously formed in the same manufacturing process. The first cover insulating layer 250B-1 and the second cover insulating layer 250B-2 may be formed to have substantially the same thickness (e.g., in a vertical direction), but according to an example embodiment, a thickness of the second cover insulating layer 250B-2 may be greater than the thickness of the first cover insulating layer 250B-1 in the vertical direction. In addition, according to an example embodiment, a dummy microlens may be further formed only on the second cover insulating layer 250B-2 disposed outside the first cover insulating layer 250B-1.

Referring back to FIG. 6, a second wiring structure 260 may be disposed on a lower surface 210a of the second substrate 210. The second wiring structure 260 may include a second wiring insulating film 261, a second connection wiring 264, a first lower bonding pad 266, and a second lower bonding pad 267.

The second wiring insulating film 261 may be formed on the lower surface 210a of the second substrate 210. The pixel gate layer 214 may be disposed in the second wiring insulating film 261. The second wiring insulating film 261 may include, for example, at least one of silicon oxide, silicon nitride, silicon oxynitride, and a low-k material having a dielectric constant lower than that of silicon oxide.

A second connection wiring 264 may be disposed in the second wiring insulating film 261. The second connection wiring 264 may be electrically connected to a storage node region 213, a photoelectric conversion element 212, and a pixel gate layer 214.

The first lower bonding pad 266 may not be connected to the second connection wiring 264. On the other hand, the second lower bonding pad 267 may be connected to the second connection wiring 264. The second lower bonding pad 267 may be connected to the second connection wiring 264 through a lower bonding pad via 265.

A via electrode 530 may penetrate through the first chip structure 100 and the second chip structure 200 to electrically connect the electrode pad 11 and the conductive pattern 510 of the redistribution structure 500. The via electrode 530 may include an insulating layer 531 covering an upper surface 100b of the first chip structure 100 and covering a sidewall of the via hole V, and a conductive material layer 532 filling an inside of the via hole V.

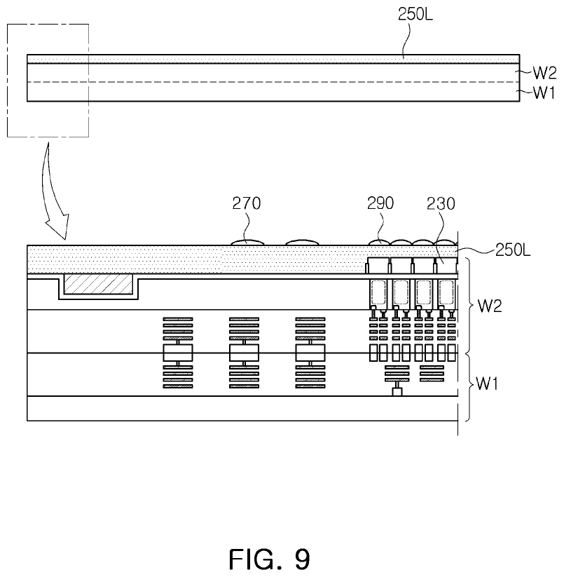

Next, a manufacturing process of the image sensor 1 according to an example embodiment will be described with reference to FIGS. 9 to 15. Configurations indicated by the same reference numerals as those of the above-described example embodiments are the same configurations as those of the above-described example embodiments, and thus a detailed description thereof will be omitted.

Referring to FIG. 9, a cover insulating material layer 250L may be formed on a second wafer W2. The cover insulating material layer 250L may cover color filters 240 disposed on the second wafer W2 to form a planarized upper surface. In this manner, the cover insulating material layer 250L may planarize the color filters 240 so that a solid and continuous planar surface is formed to cover the color filters 240. The cover insulating material layer 250L may include a material including a resin layer, an oxide film, or a combination thereof. The second wafer W2 may be provided in a state in which the first wafer W1 is directly bonded thereto. A plurality of the first chip structures 100 described with reference to FIG. 6 may be disposed on the first wafer W1, and a plurality of the second chip structures 200 described with reference to FIG. 6 may be disposed on the second wafer W2.

Microlenses 290 may be formed in a region overlapping the color filters 230 on an upper surface of the cover insulating material layer 250L. Dummy microlenses 270 may be formed on the upper surface of the cover insulating material layer 250L not overlapping the color filters 230.

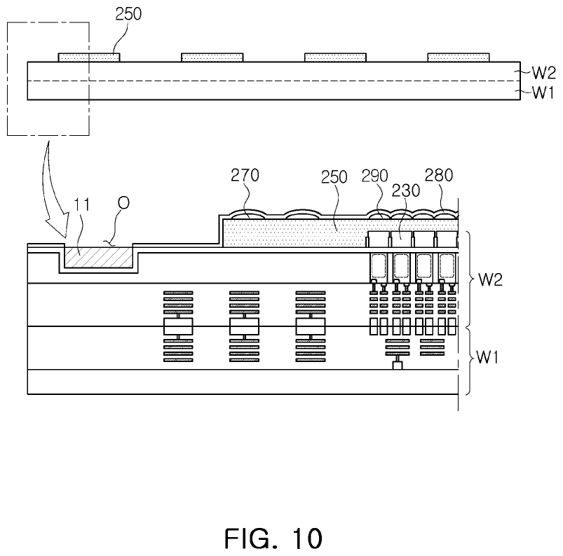

Referring to FIG. 10, a cover insulating layer 250 may be formed on a second wafer W2. The cover insulating layer 250 may be formed by removing a region in which microlenses 290 and dummy microlenses 270 are not disposed in the cover insulating material layers 250L of FIG. 9. A protective layer 280 covering an upper surface a side surface of the cover insulating layer 250 and an upper surface of the second wafer W2 may be formed, and one region of the protective layer 280 may be removed to form an opening O through which the electrode pad 11 is exposed.

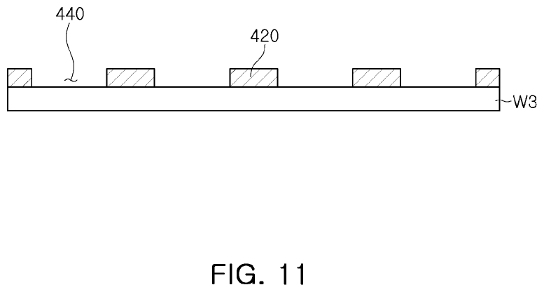

Referring to FIG. 11, a support portion 420 may be formed on a third wafer W3. The third wafer W3 is for forming a light-transmissive substrate 410 of the light-transmissive cover 400 described above with reference to FIG. 6. The third wafer W3 may be formed of one of soft glass, fused silica, and fused quartz. The support portion 420 may be formed of a photosensitive resin. In an example embodiment, the support portion 420 may be formed of photoresist. The support portion 420 may be provided by coating a photoresist layer on an upper surface of the light-transmissive cover 400, and forming a pattern thereon. A process of forming the support portion 420 on the third wafer W3 may be performed irrespective of an order, separately from the process of forming the cover insulating material layer 250L on the second wafer W2 of FIG. 9 described above.

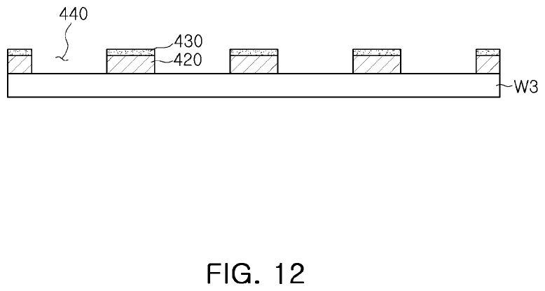

Referring to FIG. 12, an adhesive layer 430 may be formed on an upper surface of the support portion 420. For example, the adhesive layer 430 may be formed by applying an epoxy resin.

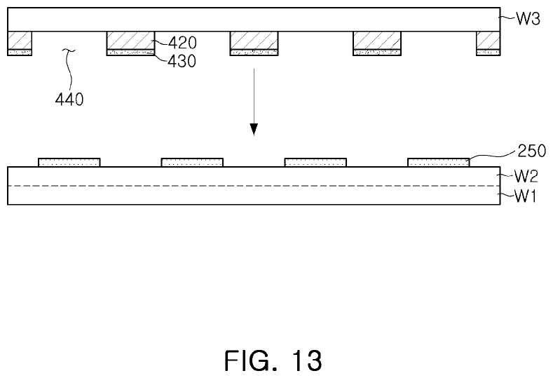

Referring to FIG. 13, the third wafer W3 may be turned over and bonded to the second wafer W2 of FIG. 10 described above.

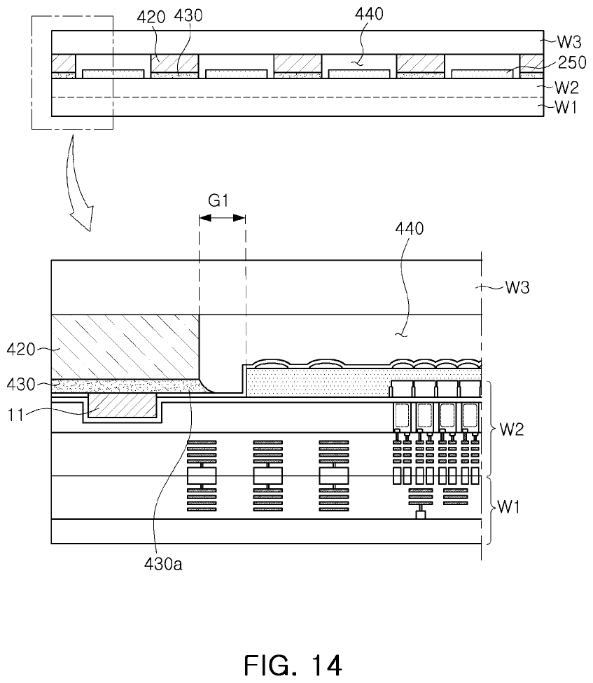

Referring to FIG. 14, in a process of attaching the third wafer W3 to the second wafer W2, the adhesive layer 430 may be pressed by the support portion 420 so that a portion 430a of the adhesive layer 430 may penetrate into the recess portion 440 of the cover insulating layer 250, but due to a step difference of the cover insulating layer 250 and a separation distance G1 from the support portion 420, the portion 430a of the adhesive layer 430 penetrating into the recess portion 440 may be blocked from being disposed on the upper surface of the cover insulating layer 250 and covering a pixel array region PAR.

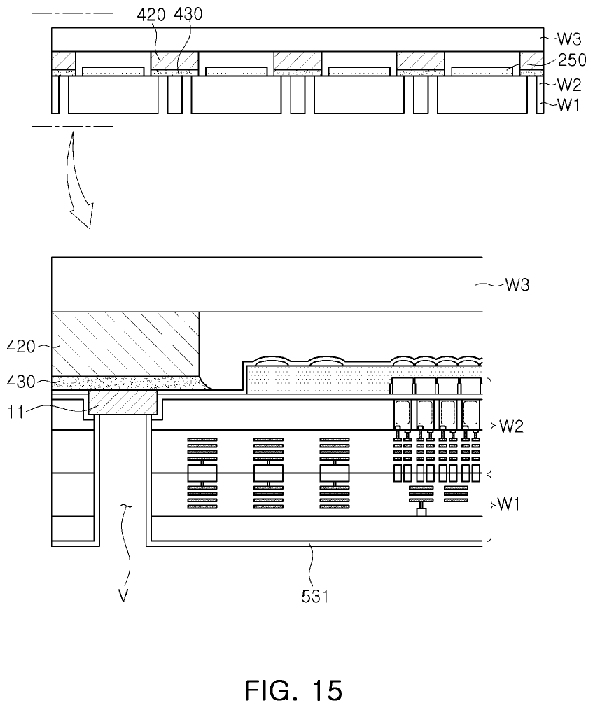

Referring to FIG. 15, a via hole V through which the electrode pad 11 is exposed penetrating through the first wafer W1 and the second wafer W2 may be formed, and an insulating layer 531 covering a sidewall of the via hole V and a lower surface of the first wafer W1 may be formed. In a subsequent process, an inside of the via hole V is filled with a conductive material layer and diced, the image sensor 1 of FIG. 6 is manufactured.

As set forth above, by blocking an adhesive layer with a cover insulating layer formed on a wafer, an image sensor in which the adhesive layer is prevented from penetrating into a pixel array region in a process of bonding the wafers with the adhesive layer may be provided.

The various and advantageous advantages and effects of the present inventive concept are not limited to the above description, and may be more easily understood in the course of describing a specific embodiment of the present inventive concept.

While example embodiments have been shown and described above, it will be apparent to those skilled in the art that modifications and variations could be made without departing from the scope of the present invention as defined by the appended claims.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Also, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

1. An image sensor, comprising:
a first chip structure;
a second chip structure, disposed on the first chip structure, and in which pixels which each include a photoelectric conversion element are defined; and
a light-transmissive cover bonded to an edge region of the second chip structure by an adhesive layer and having a recess portion covering a region in which the pixels are accommodated,
wherein the second chip structure includes,
a substrate having a first surface and a second surface opposite to each other;
color filters disposed on the second surface of the substrate to correspond to the pixels;
a cover insulating layer covering the color filters, and accommodated in the recess portion and disposed to be horizontally spaced apart from an outer boundary of the recess portion; and
microlenses disposed on the cover insulating layer to correspond to the pixels, respectively,
wherein an upper surface of the cover insulating layer is at a higher vertical level than the second surface of the substrate, and has a step difference of 3 μm to 15 μm with respect to the upper surface of the substrate.

2. The image sensor of claim 1, wherein the cover insulating layer has a horizontal separation distance from the outer boundary of the recess portion in a range of 5 μm to 300 μm.

3. The image sensor of claim 1, wherein when viewed in plan view, the cover insulating layer comprises,
a first region overlapping the color filters; and
a second region surrounding an external side of the first region.

4. The image sensor of claim 3, further comprising,
dummy microlenses disposed on the second region of the cover insulating layer.

5. The image sensor of claim 4, wherein a diameter of the dummy microlenses is greater than a diameter of the microlenses.

6. The image sensor of claim 5, wherein a thickness of the cover insulating layer is greater than a thickness of each dummy microlens.

7. The image sensor of claim 1, wherein when viewed in plan view, each corner of the cover insulating layer is rounded.

8. The image sensor of claim 1, wherein the light-transmissive cover comprises
a support portion forming a boundary of the recess portion and bonded to the second surface of the substrate; and
a light-transmissive substrate covering the recess portion.

9. The image sensor of claim 8, wherein the support portion is made of photoresist, and
wherein the light-transmissive substrate is made of one of soft glass, fused silica, and fused quartz.

10. The image sensor of claim 8, wherein the support portion is made of a material, different from that of the light-transmissive cover.

11. The image sensor of claim 1, further comprising:
electrode pads disposed at an upper surface of the second chip structure and spaced apart from the cover insulating layer,
a redistribution structure disposed on a lower surface of the first chip structure and including a conductive pattern and an insulating layer covering the conductive pattern, and
a via electrode penetrating through the first chip structure and the second chip structure, to electrically connect the electrode pads and the redistribution structure.

12. The image sensor of claim 11, wherein the electrode pads are disposed in the edge region of the second chip structure.

13. An image sensor, comprising:
a substrate in which pixels which each include a photoelectric conversion element are defined, the substrate having a first surface and a second surface opposite to each other;
a light-transmissive cover bonded to an edge region of the second surface on the second surface of the substrate by an adhesive layer and having a recess portion covering a region in which the pixels are accommodated;
a cover insulating layer disposed on the second surface of the substrate and accommodated in the recess portion and disposed to be horizontally spaced apart from an outer boundary of the recess portion; and
microlenses disposed on the cover insulating layer to correspond to the pixels, respectively,
wherein the cover insulating layer is at a higher vertical level than the second surface of the substrate and has a step difference with respect to the second surface of the substrate in a range of 3 μm to 15 μm.

14. The image sensor of claim 13, wherein an upper surface of the cover insulating layer has a planarized region, and the microlenses are disposed on the planarized region.

15. The image sensor of claim 13, wherein the cover insulating layer comprises a first cover insulating layer and a second cover insulating layer spaced apart from the first cover insulating layer and disposed on an external side of the first cover insulating layer.

16. The image sensor of claim 15, wherein the second cover insulating layer extends along the external side of the first cover insulating layer.

17. The image sensor of claim 15, wherein an upper surface of the first cover insulating layer is at the same vertical level as an upper surface of the second cover insulating layer.

18. The image sensor of claim 15, further comprising dummy microlenses disposed on an upper surface of the second cover insulating layer.

19. The image sensor of claim 15, further comprising
color filters disposed on the second surface of the substrate to correspond to the pixels,
wherein the first cover insulating layer has a region overlapping the color filters.

20. (canceled)

21. (canceled)

22. An image sensor, comprising:
a substrate on which pixels which each include a photoelectric conversion element are disposed, the substrate having a first surface opposite to a second surface;
a support platform having a first surface connected to the first surface of the substrate and a second surface opposite thereto, the support platform including an inner wall connecting the first surface of the support platform to the second surface of the support platform and having a light-transmissive window in which the pixels are accommodated;
a light-transmissive substrate disposed on the second surface of the support platform, and covering the light-transmissive window;
color filters disposed on the first surface of the substrate to correspond to the pixels;
a cover insulating layer covering the color filters and accommodated in the light-transmissive window and disposed to be horizontally spaced apart from a sidewall of the light-transmissive window; and
microlenses disposed on the cover insulating layer to correspond to the pixels, respectively,
wherein the cover insulating layer is at a higher vertical than the first surface of the substrate.

23. (canceled)
